(19) United States
(12) Patent Application Publication
(10) Pub. No.: US 2016/0005910 A1
(43) Pub. Date: Jan. 7, 2016

(54) VERTICAL MULTI-JUNCTION PHOTOVOLTAIC CELL WITH REVERSE CURRENT LIMITING ELEMENT

(71) Applicant: Bernard L. SATER, Strongsville, OH (US)

(72) Inventor: Bernard L. Sater, Strongsville, OH (US)

(21) Appl. No.: 14/769,881

(22) PCT Filed: Feb. 26, 2014
(86) PCT No.: PCT/US14/18655

§ 371 Date: Aug. 24, 2015

Related U.S. Application Data
(60) Provisional application No. 61/851,108, filed on Mar. 1, 2013.

(51) Int. Cl. H01L 31/0687; H01L 31/047

(52) U.S. Cl. CPC H01L 31/0687; H01L 31/047

(57) ABSTRACT

A vertical multi junction (VMJ) photovoltaic cell comprising a plurality of layers of PN junctions, wherein at least one of the layers is reversed relative to the other layers so that the VMJ cell will inherently limit reverse current flow through the cell and thermal effects attendant to such reverse current flow.

### CROSS REFERENCE TO RELATED APPLICATIONS

This application claims priority to and the benefit of U.S. Provisional Application Ser. No. 61/851,108, filed Mar. 1, 2013, entitled VERTICAL MULTI-JUNCTION PHOTOVOLTAIC CELL WITH REVERSE CURRENT BLOCKING ELEMENT. The above-identified provisional application is incorporated herein by reference in its entirety for all purposes.

### FIELD OF THE INVENTION

The present invention relates to the field of vertical multi-junction photovoltaic cells, and more particularly to VMJ photovoltaic cells that inherently limit reverse current.

### BACKGROUND

Vertical multi-junction (“VMJ”) solar cells are ideally suited for efficient operation in high intensity photovoltaic (“PV”) concentrator power systems. A prior art conventional VMJ cell, shown schematically in FIG. 1, is an integrally bonded, series-connected array of miniature vertical silicon junction unit cells that has the form of a small square slab measuring approximately 1 cm on each side and a thickness of 0.05 cm. Because of its unique orientation to illumination, it is also descriptively referred to as an “edge-illuminated” VMJ cell.

The prior art conventional process for fabricating a VMJ cell are described in U.S. Pat. No. 4,409,422 entitled “High Intensity Solar Cell.” The basic steps are illustrated in FIG. 2. A significant number of diffused p+nn+ silicon wafers 10, typically forty, each four inches in diameter and 250 microns (10 mil) thick, are metallized and assembled into a stack 14 in their p+nn+ order, then alloyed together under pressure and temperature to form a multi-wafer stack 16 that is 1 cm high. The stack of diffused wafers 16, when cut into 0.05 cm strips (as indicated at 18) that are then further sawn into 1 cm cells, yields more than five hundred VMJ cells 20 that are 1 cm×1 cm in area and 0.05 cm thick, with a cell surface that exposes forty series-connected p+nn+ junctions for high voltage operation. Exposed silicon surfaces are saw-damage etched and passivated with an anti-reflection coating on the illuminated surface. Electrical contact leads are bonded on opposite edges of each cell 20. An edge-illuminated vertical junction p+nn+ unit cell is schematically shown in a magnified view 22, where the Greek symbol lambda (“A”) represents incident sunlight. VMJ cells can be fabricated in similar fashion with diffused p+pn+ silicon wafers, or with other semiconductor materials, or with different numbers of junctions, not to mention wafers of other sizes, or portions of wafers. The semiconductor materials could also be from sources other than wafers.

Major design advantages of the conventional VMJ cell have been discussed in an article by B. L. Sater and N. D. Sater entitled “High Voltage Silicon VMJ Solar Cells for up to 1000 Suns Intensities” (Photovoltaic Specialists Conference 2002; Conference Record of the Twenty-Ninth IEEE, May 19-24, 2002, pp. 1019-1022). In brief, the VMJ cell is advantageously a high voltage solar cell with multiple series-connected vertical junction unit cells with internal ohmic contacts, which provides near optimum current collection without sheet resistance, current crowding, or blockage of illumination. Efficient performance at high intensities of up to 2500 suns has been demonstrated. (See FIG. 3, which is a chart showing the current versus voltage performance of a cell under a number of illumination conditions.) Furthermore the VMJ cell is rugged not only electrically, but also mechanically and thermally.

The VMJ cell can be used in a PV optical concentrator system. Two basic design approaches for such concentrator systems are shown in FIG. 4, which depicts a distributed array 24 having multiple optical concentrator elements 28 and one VMJ cell per concentrator element, and a dense array 26 having one optical concentrator 30 but multiple VMJ cells. The FIG. 4 systems use reflective concentrators 28 and 30 but, alternatively, refractive concentrators (lenses) can be used to concentrate the light. Multiple optical concentrator elements may in fact be used to concentrate the light, which may provide reduced cost, improved uniformity of illumination on the receiver, simplified tracking accuracy requirements, or other advantages. In addition, there may be combinations of these approaches, such as a group of medium size concentrators with each having its own small dense mini-array of cells. The VMJ cell's compact design permits easy interconnection of output leads in densely packed arrays or mini-arrays, and by virtue of its very high reverse breakdown voltage characteristics (several thousands of volts) does not need bypass diode protection.

FIG. 5 illustrates a prior art solar power installation employing high intensity high power PV concentrators systems using VMJ cells mounted in a dense array. Because of their inherent advantages, such systems can provide viable cost-effective solar power. Generally, PV concentrators employ larger areas of lower cost materials, like glass mirror reflectors, to collect and concentrate sunlight on smaller areas of more expensive PV cells. Thus, such systems effectively reduce the amount of expensive PV semiconductor material required. In this way, PV concentrators with VMJ cells can provide lower overall system cost per watt metrics.

Although high intensity high power PV concentrator systems, as illustrated in FIG. 5, are more complex than conventional fixed, non-concentrator (i.e., one-sun) solar cell panels, there are performance advantages besides costs. For example, conversion efficiency of VMJ cells increases with intensity, and sun-tracking produces more energy over time. Furthermore when active cooling systems are used to cool VMJ cells, valuable thermal energy is available to users for various applications such as absorption air conditioning and refrigeration, space heating and hot water applications (see FIG. 5). This benefit is not available with conventional one-sun solar cell panels.

Nevertheless, high intensity high power PV concentrator systems present challenging engineering hurdles in structural, sun-tracking, optical, thermal, and electrical aspects that are not normally encountered with fixed one-sun solar cell panels. For example, the structure and tracking must maintain stability and alignment, the optics must assure good optical uniformity on the array of VMJ cells, and the heat sink must effectively maintain VMJ cells' operating temperatures within a desired range for good performance, while efficiently cooling and either dissipating or transferring excess heat to the thermal system.

Several engineering hurdles are relevant to the present invention. One such hurdle concerns packing density. Packing density is a term used to identify the percentage of total receiver area that is occupied by active cell area that produces electrical power when illuminated. VMJ cells closely packed in dense arrays or mini-arrays are well suited for optimal energy conversion in the intense focal regions of large solar concentrators, but it is desirable in such systems to maximize packing density. Gaps between cells, interconnection wires, buffer zones, and other electrical devices that occupy the receiver area all reduce packing density, which results in reduced system efficiency. Concentrated sunlight that does not fall on active cell area is considered ‘lost’, because that sunlight does not get converted to electricity. For maximum efficiency, packing density of VMJ cells should be as high as possible to minimize loss of concentrated sunlight.

A second engineering hurdle concerns possible thermal degradation of the VMJ cells. At 500 suns intensity (50 watts/cm²), a forty junction 1 cm² area VMJ cell at 24% efficiency will produce 0.5 amps at 24 volts Vₘₐₓ for 12 watts Pₘₐₓ of output power under rated 25° C. standard test conditions (STC). However, forty-junction VMJ cell tests conducted by the inventor at higher operating temperatures show Pₘₐₓ power degradation of around 0.03%/° C. and Vₘₐₓ voltage degradation of about 0.063 volts/° C. Therefore, for good system performance, it is important to maintain good thermal control of operating VMJ cells at high intensities to minimize electrical output degradation.

A third hurdle is that, because VMJ cells have negative voltage-temperature coefficients (i.e. decreasing voltage with increasing temperature), there is some risk of thermally induced internal parasitic currents or even thermal runaway of individual cells in arrays or networks of VMJ cells. The risk arises because, in such arrays or networks, a number of VMJ cells may be connected in parallel. If, due to inadequate thermal control, a VMJ cell overheats while operating at high intensity, its operating voltage will decrease in accordance with the cell's negative voltage-temperature coefficient. The resulting lower operating voltage of the hotter VMJ cell will make it a potential back flow current sink (reversed current) for other normally operating higher voltage cells that are connected in parallel with it.

An example of this potential thermal problem can be seen in FIG. 6 where four prior art conventional VMJ cells, marked A through D, are connected in a parallel side-by-side string. If cell C were to become hotter than the other cells, its sourced voltage would drop due to its negative temperature coefficient. Since all cells are connected in parallel, however, the cells are forced to operate at the same voltage. The hotter cell C, which is sourcing a lower voltage than the other cells, will thus become somewhat forward-biased and will sink some current from cooler cells A, B and D. Those currents I_{A}, I_{B} and I_{D} into forward biased cell C will decrease the voltage outputs of cells A, B and D while increasing the voltage across cell C until equilibrium is restored. Note that this will occur even when the entire string output current I_{O} is zero, e.g. when the cells are disconnected from any load as shown in FIG. 6. Thus, even when the output current is zero in a string of paralleled prior art conventional VMJ cells, currents can flow internally between those paralleled cells. The internal currents are parasitic losses that hinder performance, because they are not collected as part of the string output current I_{O}.

Arrays may be much larger than only four cells, however. A dense array of VMJ cells could be fabricated in convenient size modules using four VMJ cells parallel strings, for example, as a basic connection unit. At 500 suns, each four VMJ cells parallel string would have an STC output rating of 48 watts at 24 volts. Therefore, a 16 cell dense array module of 4 strings, connected in parallel to one another, would have an STC rating of 192 watts at 24 volts, or, if the 4 strings are connected in series to one another, the module would have a rating of 192 watts at 96 volts. Convenient size modules could be further interconnected in series/parallel arrangements for higher power and voltage, when appropriately corrected for expected operating temperatures. The reverse current phenomenon described above could exist in any of these configurations, and is more likely to occur as the number of parallel interconnections of VMJ cells, strings, or modules is increased.

Beyond the parasitic losses described above there exists a possibility of thermal runaway, which exists whether the arrays are large or small, and whether interconnected in parallel or a combination of series and parallel. Increasing back flow current in a hot VMJ cell may lead to further power dissipation and further heating, which in turn causes even lower voltage with even higher reverse current heating, and so on. In a worst-case scenario, extreme heating could cause permanent cell damage that could affect an entire array of interconnected cells, strings, or modules. Considering a sixteen parallel cell module, for example, fifteen of the sixteen cells in the module could feed current and thus power to the single hot cell; and that power density would far exceed the normal operating solar flux power density.

The issue arises due to non-uniformities in device performance, thermal management, and/or illumination of cells within a circuit. It may be possible to avoid the issue if all cells within a circuit are identical in performance, and all of those cells are uniformly illuminated and uniformly cooled. However, complete uniformity of these characteristics is not likely. In production, devices will vary somewhat in characteristics, and thermal bonding will vary from one cell to another. At a system level, concentrators will have some non-uniformity of illumination and non-uniformity of cooling within the array. Even if the devices are identical and optical illumination and thermal management is completely uniform at a given point in time, this ideal condition may not persist at all times. For example, slight misalignment of system tracking may result in some but not all cells being illuminated, or devices may degrade in performance over time, or a portion of the heat-sink may become temporarily blocked, altering the uniformity of thermal management between cells.

In the solar panel industry, it is customary to insert a blocking diode in series with solar cell arrays to prevent reverse current flow and thereby secure certain operating benefits. When a solar cell panel is used to directly charge a battery, for example, an added series blocking diode will prevent the battery from discharging back into the solar cell panel when sunlight diminishes.

Adding blocking diodes as customarily done in the PV Industry is not considered a viable answer for dense arrays or mini-arrays of VMJ cells, because of the multitude of cells, interconnection wires, and blocking diodes that must be packed together densely and efficiently within the receiver area. The present invention provides a better solution, which inherently limits reverse current flow with minimal affect on the receiver's packing density.

### SUMMARY OF THE INVENTION

An object of the invention is to produce within a VMJ cell, a simple integral element that performs the same function as a separately added blocking diode that is generally employed by the PV Industry in solar cell arrays to prevent a reverse current flow problem.

In accordance with the present invention, a vertical multi-junction (VMJ) photovoltaic cell is provided that comprises a plurality of layers of PN junctions, wherein at least one of the layers is reversed relative to the other layers.

In accordance with one example embodiment of the present invention, an array of vertical multi-junction photovoltaic cells is provided. The array comprises a plurality of vertical multi-junction photovoltaic cells, where each cell has a plurality of layers of PN junctions, all of the layers aligned so that the PN junctions are in electrical series with one another. At least one other layer of PN junction is provided in each cell, aligned so that the other layer is in electrical anti-series with the plurality of layers of PN junctions. The plurality of vertical multi-junction photovoltaic cells are interconnected in parallel with one another directly, without any intervening reverse-current limiting elements.

In accordance with another example embodiment of the present invention, a method is provided for making a vertical multi-junction photovoltaic cell. The method includes the steps of stacking a plurality of wafer elements one on top of the other in a common orientation, and adding to the stack at least one additional wafer element in a reversed orientation relative to the other wafer elements of the stack to thereby form a combined stack including a reversed wafer. The combined stack is sawn to form individual die and the individual die are further processed to form the vertical multi-junction photovoltaic cells. The method may be performed using whole wafers or just portions of wafers, or using semiconductor materials in a form other than wafers.

### BRIEF DESCRIPTION OF THE DRAWINGS

The foregoing and other features and advantages of the present invention will become apparent to those skilled in the art to which the present invention relates upon reading the following description with reference to the accompanying drawings, in which:

FIG. 1 is a perspective representation of a prior art vertical multijunction (“VMJ”) solar cell;

FIG. 2 is a representation of the basic steps of a known process used to create a VMJ of the type shown in FIG. 1;

FIG. 3 is a graph illustrating the high flux operation of known VMJ cells as shown in FIG. 1;

FIG. 4 illustrates examples of known solar collector systems that have been considered for use with arrays of VMJ cells;

FIG. 5 is a block diagram of a conventional solar power installation including a dense array of VMJ cells, a concentrator, and assorted thermal management and system components;

FIG. 6 is a top view of a conventional array of four VMJ cells interconnected in parallel as a string, useful in understanding various thermal issues;

FIG. 7 is an electrical model of a semiconductor solar cell;

FIGS. 8(a) is a schematic of a conventional VMJ cell and 8(b) is a schematics the same cell modified to incorporate one example embodiment of the present invention;

FIG. 9 is a graph showing the manner in which the dark voltage-current characteristics of the semiconductor solar cell of FIG. 7 are altered by exposure of the junction area to illumination;

FIG. 10 is a top plan view of a silicon wafer;

FIG. 11 is a side elevation view of a portion of the wafer of FIG. 10;

FIG. 12 is a side elevation view of a portion of a stack of wafers incorporating one example embodiment of the present invention; and,

FIG. 13 is a perspective view of the VMJ cell fabricated from the wafer stack shown in FIG. 12.

### DETAILED DESCRIPTION

A conventional single-junction solar cell can be modeled with the equivalent circuit shown in FIG. 7, comprising an ideal diode D, a series resistor Rₛ, a shunt resistor Rₛₕ bypassing the ideal diode D, and a current source S in parallel with the ideal diode D. When the pn junction of the diode is exposed to light, e.g. sunlight, photons create current carriers I_{L} that bias the diode pn junction to generate the solar cell output current (I) and voltage (V). However, if the solar cell output voltage terminals (V) are connected to a higher voltage source, current (I) will reverse (i.e. back current sinking will occur). A solar cell can thus either be a power generator or a power sink, depending on the direction of current flow. This reverse current flow can create significant issues in arrays of parallel-connected VMJ cells.

The manifestation of the problem in arrays of VMJ cells, and the nature and benefits of the solution provided by the present invention, may be better understood by comparing the prior art VMJ cell design of FIG. 8(a) with the new, modified design of FIG. 8(b). In these figures, for simplicity of illustration, each junction is represented as a simple diode in lieu of the more complicated FIG. 7 model. In FIG. 8(a), a prior art forty junction VMJ cell is represented as a series-connected string of forty illuminated-junction pn diodes. When the forty junctions are exposed to light, the illustrated VMJ cell will source current out of the positive cell terminal at a certain voltage (V) and current (I). Unfortunately, if a higher voltage (V) is applied across the positive and negative terminals of the VMJ cell by an external circuit, current (I) will flow through the string in the reverse direction. Thus, the VMJ cell of FIG. 8(a) suffers from the same reverse current problem described above with respect to the FIG. 7 single-junction solar cell. This back flow current is the source for a potentially serious problem.

In arrays where conventional prior art VMJ cells are connected in parallel, the reverse cell currents described above can flow within the array from cooler cells generating higher voltage cells to hotter cells generating lower voltages. If one VMJ cell in the array becomes hotter than the remaining cells, the hot VMJ cell output voltage may be less than the peak power voltage Vₘₐₓ of the other cells. The full Pₘₐₓ of the other cells in the array would then be available to drive additional power dissipation in the hotter cell. Such additional reverse current power dissipation is significantly greater than the dissipation expected during normal operation, and it could quickly overwhelm the thermal heat sink design capability for VMJ cell cooling, resulting in permanent damage to that VMJ cell and degradation of the entire array.

A thermal runaway condition could occur whenever a VMJ cell thermal control ° C./watt impedance of a hot cell became substantially inadequate to prevent even more heating due to decreasing operating voltages and resulting increasing reverse current sinking, further heating of the cell, and so on. Thus, the fate of the cell will hinge on a vague energy balance relationship—the point at which an incremental increase in power dissipation in the VMJ cell exceeds the incremental ability of the cell to extract heat and thereby maintain thermal control.

This worst case scenario could be provoked by any number of root causes. For example, a poor thermal bond of a VMJ cell within the array could result in poor thermal conduction from the cell to the underlying heat sinks, making the cell more susceptible to hotter operating temperatures. A PV concentrator could have a number of issues that would affect the uniformity of illumination incident upon the cells within the array, causing an imbalance in the electrical characteristics and the operating conditions of the VMJ cells within the array. Structure misalignment could skew the illumination pattern. Errors in sun-tracking could offset the illumination pattern. Optical imperfections could cause illumination to be distributed in a non-uniform (e.g. Gaussian) manner in the focal region. Moreover, soiling of the concentrator could cause non-uniformities of illumination between interconnected cells, strings, and modules within the array.

Such worst-case damage has been observed in a densely packed array of twenty prior art VMJ cells thermal mounted on a water-cooled heat sink. In that case, the peak power output Pₘₐₓ of the array permanently decreased by more than 50% in field operation at high intensities. After the output leads of the single permanently damaged VMJ cell were detached from the remaining nineteen cells in the dense array, however, the array output power was restored in the expected proportion of 19/20th of original power (i.e. the expected power output of the remaining nineteen of the original twenty good cells in the dense array).

A discrete, external blocking diode may be added to the output of each VMJ cell to block reverse current and thus assure power generation only. Unfortunately, adding separate blocking diodes adds cost and may reduce packing density and thus reduce system efficiency when the blocking diode and the interconnection wires occupy receiver area. Moreover, the additional connection points add complexity and cost, and represent additional failure points.

The inventor has discovered that a reverse current limiting solution can be integrated into the VMJ cell, itself, during the fabrication of the cell, to produce a cell that will inherently limit reverse currents without the need for discrete, external blocking diodes. This solution is schematically illustrated in FIG. 8(b).

In contrast to the prior art design of FIG. 8(a), the FIG. 8(b) design has the top diode D_{R} of the series-connected string of forty diodes connected in anti-series with the other thirty-nine diodes. That is, the cathode of the reversed diode D_{R} is connected to the cathode of the top-most diode of the remainder of the string. The inclusion of the reversed diode D_{R} will limit current (I) flowing in the reverse direction into the VMJ cell when the dense array to which it belongs is illuminated, in a manner similar to the reverse-current blocking that would be provided by a separate blocking diode.

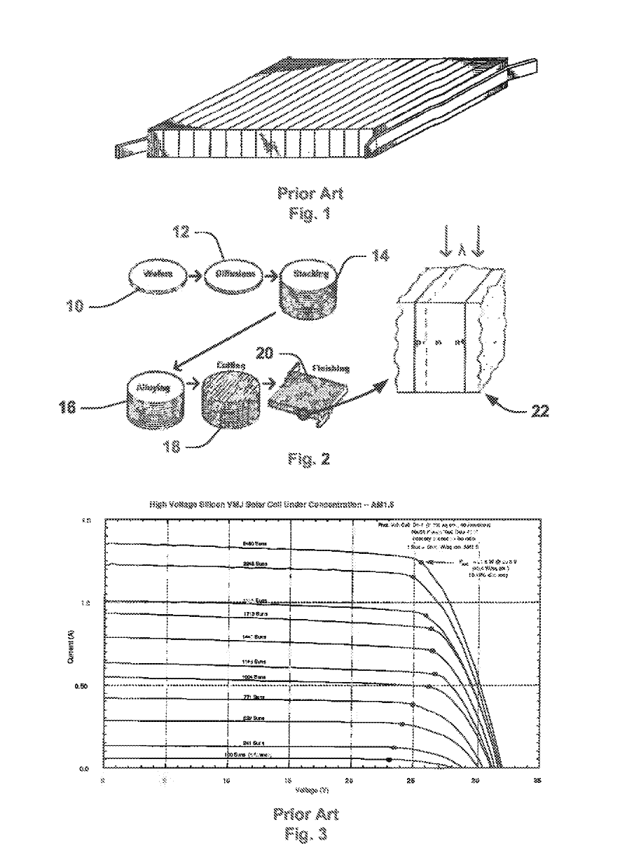

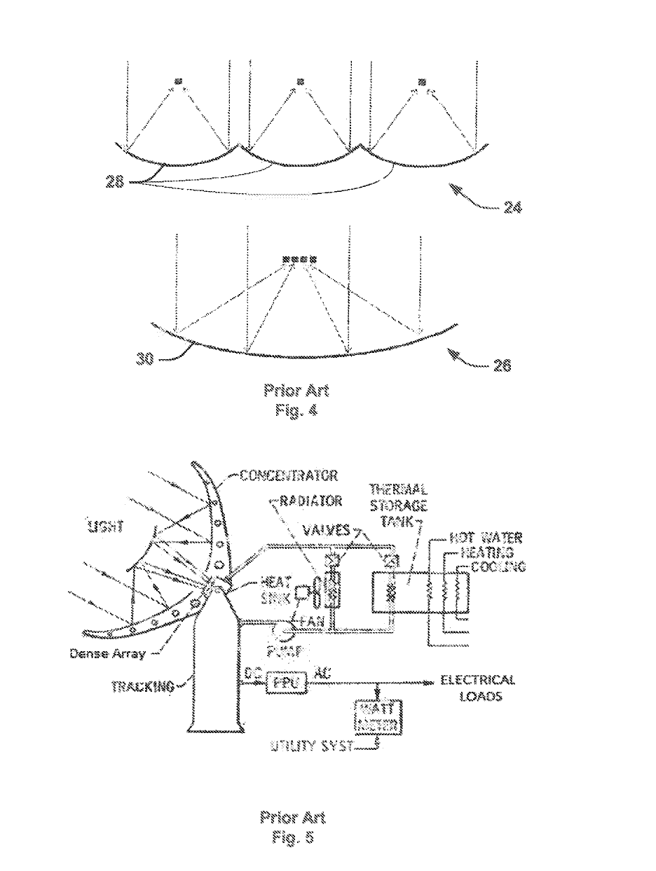

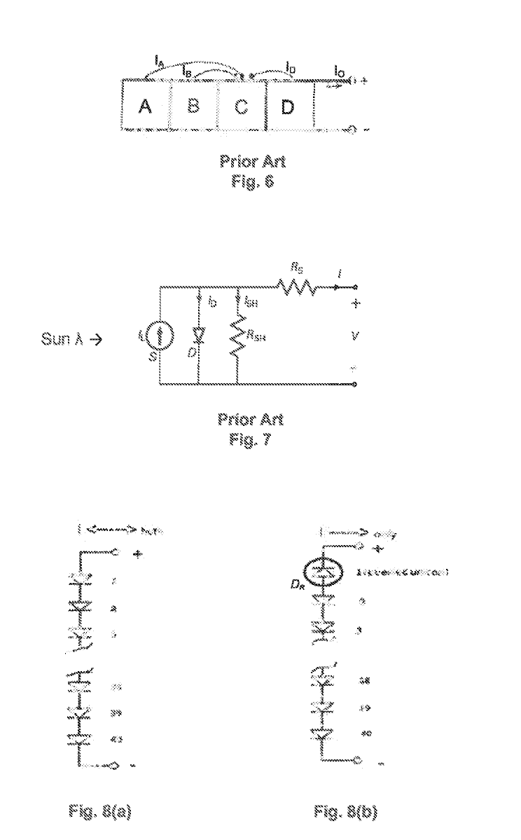

This beneficial design change is accomplished during the fabrication of the VMJ cells by reversing one wafer when assembling a stack of wafers, or reversing a partial wafer when assembling a stack of partial wafers. Such wafer reversal is contrary to the prior art, as shown for example in U.S. Pat. No. 4,409,422 and FIGS. 2 and 8(a), in which all wafers of the VMJ cell are stacked so that the forward and blocking directions of each wafer are orientated in the same direction. More specifically, the prior art conventional VMJ cell fabrication has all wafers stacked in same orientation order of p+nn+; p+nn+; p+nn+; p+nn+; and so on.

The wafer reversal in accordance with this embodiment of the present invention could be done anywhere in the stack but, assuming it is the first wafer, the specific orientation would then be n+np+; p+nn+; p+nn+; p+nn+; and so on. Reversing the forward and blocking direction of one wafer in the entire stack of wafers now secures an important benefit not realized with the prior design. That is, the new VMJ cell will inherently limit back flow of current, without the need for a separate blocking diode.

If the reversed wafer replaces one of the original forty wafers of the VMJ cell, the new VMJ cell will be the same size as prior VMJ cells. Even if the reversed wafer is added to the prior forty wafers rather than replacing one of those wafers, the increment in size to the VMJ cell will be negligible. Because of this and also because the new cell does not require any external devices or interconnection wire, the new VMJ cell will have minimal impact to the packing density of dense VMJ cell arrays or mini-arrays. Furthermore, the integrated current limiting feature does not add significant complexity to VMJ manufacture because it can be added using the same techniques that are employed to form the VMJ cell itself. The new VMJ cell thus effectively eliminates the potential hot cell problem with only a minor impact in system efficiency, and without significant added cost or complexity.

It may be desirable in some circumstances to stack portions of wafers rather than entire wafers. In such circumstance, the wafers could first be sawn into shapes, e.g. strips, of a uniform size selected to optimize the fabrication process. For example, the wafers could be sawn into 1 cm strips and the strips then stacked and otherwise processed to fabricate VMJ cells incorporating the present invention.

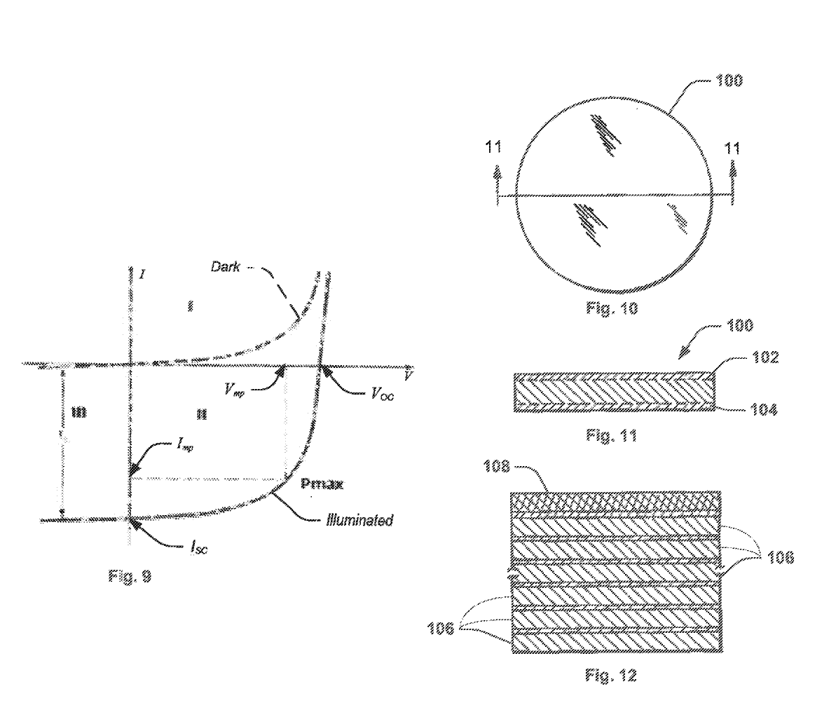

To help better understand the electrical operation of the reversed layer in the VMJ cell, the current (I) versus voltage (V) characteristics of a single pn junction solar cell are illustrated in the graph of FIG. 9. The current-voltage characteristic of a dark (un-illuminated) pn junction is represented by the dotted-line curve and the current-voltage characteristic of an illuminated pn junction is represented by the solid-line curve. The dark current-voltage curve is the familiar curve of a conventional pn diode. The illuminated current-voltage curve illustrates that an illuminated solar cell normally operates in quadrant II, generating a current in a negative polarity (cathode to anode) and delivering power to a load at Pₘₐₓ (Iₘₚ@Vₘₚ). When short-circuited, the solar cell operates at a maximum current of I_{SC}, and when open-circuited, the solar cell operates at a maximum voltage of V_{OC}.

However an illuminated solar cell will operate in quadrant I when it is forward biased by an external voltage source (V) that is higher that V_{OC}. Such operation is undesirable because, in quadrant I, the current will be sunk rather than sourced and the solar cell will be dissipating power, not delivering it. The present invention prevents operation of the unit cells in quadrant I and thus prevents the undesirable dissipation of power attendant therewith.

The reversed unit cell, on the other hand, will operate in quadrant III when it is reversed biased (as it will be when it is protecting the VMJ cell by preventing back-flow of current), this quadrant III operation will not materially impact the functioning of the VMJ cell. The quadrant III operation of the reversed unit cell will be discussed later herein in more detail.

A VMJ cell with a reversed unit cell according to this invention will effectively limit reverse current and the serious thermal problems that are attendant therewith, without the need for a separate blocking diode, so that the overall system will be more tolerant to illumination imbalance, heat sink deficiencies, and differences between characteristics of devices within the array. Although it is still possible for one VMJ cell to become thermally degraded, the operation of the thermally degraded cell will not significantly affect the overall operation of the system. Moreover, this benefit is gained without significantly diminishing packing density or adding circuit or module cost or complexity.

The output voltage of the cell will be diminished by the diode offset voltage (perhaps 0.6 V at high intensities) due to the inclusion of a reversed unit cell, but this effect is the same as would be experienced with discrete blocking diodes. Further, the effect could be mitigated if and as desired by increasing the number of normally-oriented unit cells that are stacked to make the VMJ cell.

In any case, the invention preserves important VMJ cell design aspects that allow high packing densities in dense arrays for efficient operation in high power high intensity PV concentrators. Packing density can be increased significantly over designs that might include separate blocking diodes, as the discrete diodes and attendant connections can be omitted. The new VMJ cell invention thus preserves advantageous design aspects of dense arrays and mini-arrays that are not possible when separate blocking diodes are instead employed, occupying area within the receiver.

FIGS. 10 through 12 further illustrate the example embodiment of the present invention. In FIG. 10 an n-type silicon wafer 100 is illustrated. As indicated previously, the wafer may for example be four inches in diameter and 250 microns thick. Wafer 100 will be doped p+ on one surface 102 and n+ on the opposite surface 104, thereby creating the p+nn+ doping architecture described herein and shown in the FIG. 11 sectional view of the diffused wafer. FIG. 12 is a sectional view of a portion of a stack of forty silicon wafers (or portions of wafers) although, for simplicity of illustration, relative dimensions are exaggerated, not all wafers are shown, and not all doping layers of each wafer are shown. In the described embodiment thirty-nine of the silicon wafers or portions of wafers 106 are stacked in p+nn+ order. The remaining silicon wafer 108, shown in the top of the stack in FIG. 12, is turned upside down so that it is reversed in the stack relative to the stacking order of the other thirty-nine wafers. Wafer 108 thus has a reversed n+np+ orientation that is opposite of those of all the other wafers having the p+nn+ stacking orientation order. In this way, all VMJ cells that are cut from this stack after alloying will have a reversed unit cell as shown in FIG. 8(b).

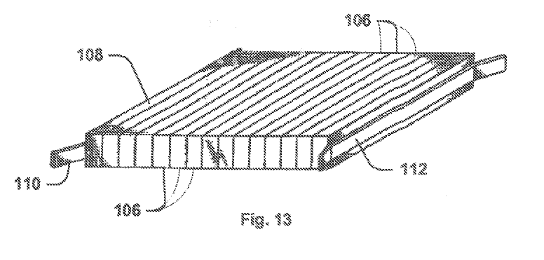

The combined stack of forty diffused and metalized wafers or wafer portions, alloyed together, forms the illustrated multi-layer stack which, again as stated previously, is 1 cm high. The stack is processed in the same manner previously described with respect to FIG. 2 to form individual VMJ squares, each 1 cm×1 cm square and 0.05 cm thick. Electrical contacts 110, 112 are mechanically and electrically attached on opposite edges of each square, thereby forming the individual VMJ cell shown in FIG. 13.

Returning now to a point mentioned briefly above, an individual junction solar cell can also operate in quadrant III (FIG. 9), conducting forward current I_{L}, if the voltage across the cell is reversed and the cell is being illuminated. A solar cell operating in quadrant III will be dissipating and not delivering power. The series-connected junctions of a conventional VMJ cell will not normally operate in this quadrant because the voltage across these cells will always be positive. The reversed unit cell of the present invention, however, will operate in quadrant III when the voltage generated by the VMJ cell drops below the voltage generated by other VMJ cells in the dense array. In this way, the new VMJ cell invention will limit back flow current, but in doing so the reversed unit cell will operate in quadrant III.

The operation of the reversed junction unit cell in quadrant III will not cause problems for the operation of the invention but, if (as has henceforth been presumed) the reversed junction unit cell is illuminated, the cell will pass some current I_{L} that will look like leakage current and will introduce some power dissipation. There are various ways of mitigating this, if such mitigation is desired.

The light-generated current I_{L} in quadrant III for the reversed junction unit cell is a function of the area of the edge-illuminated unit cell and illumination intensity. Thus, a particular level of the current I_{L} can be established by selection of the edge-illuminated unit cell area. It is possible to reduce the edge-illuminated unit cell area by selecting a thinner starting wafer for the reversed wafer than for the wafers used for the other layers of the stack making up the VMJ cell. Since all unit cells are illuminated with the same intensity, reducing the illuminated area of the reversed unit junction is a viable method for controlling I_{L}.

It may in some circumstances be beneficial to eliminate completely the light-generated current I_{L} in the reversed junction unit cell. This could readily be achieved by masking the reversed junction unit cell so that it does not receive any illumination. Masking could be implemented, for example, by coating the edge of the reversed junction unit cell with an opaque material, or by covering the junction with an appropriate light-blocking shade. Indeed, a switched-opacity coating may be implemented, enabling the unit cell to be illuminated under certain conditions and shaded under other conditions.

Although this invention disclosure is written in the context of solving a potentially serious problem with back or reversed flow current in a densely packed array of VMJ cells that are connected in parallel in high power high intensity PV concentrator systems, the invention is broad and suitable for many other applications. For example, the current back flow prevention feature provided by the invention will be useful even in a system having two VMJ cells connected in parallel within a single receiver, or where each VMJ cell has its own receiver.

Furthermore, the VMJ cell invention can also be used in single VMJ cell applications. For example, a single VMJ cell according to this invention could be used to directly charge a battery without adding a blocking diode as customarily done to protect solar cell panels when the battery is charged and the sun goes down. The new VMJ cell invention will inherently prevent back flow of current, just as a blocking diode would.

Although a forty junction VMJ cell was used in the described embodiment, any number of junctions can be used as deemed appropriate for user applications. Also other semiconductor materials besides silicon can be used in fabricating VMJ cells to take advantage of the unique inherent feature of preventing back flow of current. For example, germanium VMJ cells could be fabricated for many applications, such as for thermo-photovoltaic applications or betavoltaic batteries. Moreover, although described in the context of a stack of cells having a p+nn+ doping architecture, other architectures such as n+pp+ could alternatively be used.

The described VMJ cell of p+nn+ unit cells, with one reversed unit cell at the top, has a n+n junction on one end and a nn+ junction on the other end for contacting by contacts 110, 112 (FIG. 13). However the doping-type at the ends can be controlled by selecting where to perform the wafer/unit cell reversal. When the reversal is done at the positive end, as illustrated in the example embodiment of FIG. 8(b), the new VMJ cell will have the same n+n doping-type as the outermost doping layer at each end. If the reversal is instead done at the negative end (the opposite end of the stack of FIG. 8(b)), then the new VMJ cell will have the same p+n doping-type as the outermost doping layer at each end. In either case, the electrical functionality of each version will be the same in limiting reverse back flow of current as the invention requires.

Controlling the doping-type at the ends of the VMJ cell will be beneficial when fabricating end contacts. For example, consider the fabrication of aluminum end contacts to each of the two different versions of VMJ cell:

1. A new VMJ cell having the n+n doping-type as the outer most doping layers. When aluminum, a p-type dopant in silicon, is alloyed at an elevated temperature and time to form end contacts, there are disproportionate diffusion interactions between silicon and aluminum because silicon will diffuse faster into aluminum than vise versa. Because of this, there are potential problems. Heavily doped n+ silicon will diffuse out into aluminum leaving the n+n junction less heavily doped. At the same time, the silicon exodus could form pits allowing the aluminum, a p-type dopant, to diffuse into the silicon. These problems will degrade the semiconductor properties in the outer most unit cells. Such degradation will affect the current collection performance in those unit cells, which will limit the overall performance of the VMJ cell.

2. A new VMJ cell having the p+n doping-type as the outer most doping layers. In contrast to n+n diffusion junctions, the interactions between silicon and p-type aluminum will in essence make the p+n doping layer more p++n; and as a result, will not affect the semiconductor properties of those outer most unit cells. In addition, aluminum diffusing into silicon pits will produce additional small pn junctions that are orientated in same direction as each outer unit cell normal p+n junction. Consequently, there will not be any overall affect on VMJ cell performance.

Being able to select the doping-type at the outer ends of the new VMJ cell invention will thus be beneficial when fabricating end contacts. Nevertheless there are significant thermal expansion coefficient differences between silicon and aluminum. The thermal expansion difference will apply undesirable mechanical stresses to the outer most unit cell junctions that could affect overall VMJ cell performance. But the undesirable mechanical stresses can be eliminated by using contact materials that have thermal expansion coefficients closely matching silicon. Fortunately we can alloy an inactive undiffused low resistivity silicon wafers to each end of the stack formed during fabrication of VMJ cells that will make full electrical contact to the outer most junctions. The inactive low resistivity silicon end contacts will have the same thermal expansion properties as all active unit cells. Therefore inactive low resistivity end contacts will eliminate mechanical stress to active outer most unit cells and preserve overall performance of VMJ cells. They serve as buffers to protect active unit cells.

The low resistivity buffers protecting active unit cells, mean additional aluminum contacts or leads can be applied to these inactive low resistivity end contacts, without having mechanical stress due to the thermal expansion differences affect the VMJ cell performance. Mechanical stress on inactive low resistivity silicon will not alter its electrical characteristics.

The reversed unit cell could be incorporated within what would be non-active materials of a conventional VMJ cell, such as the end-contact or a buffer zone, as described in U.S. Pat. No. 8,106,293.

Moreover, although this patent is written in the context of reversing a single unit cell within the stack, there may be times that it is desirable for more than one unit cell to be reversed. For example if needed to provide higher blocking voltage capability, additional unit cells could be reversed to accommodate that requirement. In addition, although it is convenient to use the same wafers or portions of wafers for all unit cells in the VMJ cell, including the reversed unit cell, other alternatives are possible. The reversed unit cell could be formed of a wafer or portion of a wafer that has a different doping architecture or even different materials than the wafers used for the other unit cells in the VMJ cell. It may, for example, be desirable in some applications to design the material and doping characteristics of the reversed wafer to optimize the reverse current limiting function of that wafer.

It is expected that the present invention will find utility in many or all VMJ applications including without limitation those described in the other US patent and applications of the present inventor, including U.S. patents U.S. Pat. No. 8,106,293 and U.S. Pat. No. 8,293,079 and pending patent applications US 2010/0037943 A1 and US 20100037937 A1.

From the above description of the invention, those skilled in the art will perceive further improvements, changes and modifications. Such improvements, changes and modifications within the skill of the art are intended to be covered by the appended claims.

Having described the invention, the following is claimed:

1. A vertical multi junction photovoltaic cell comprising a plurality of layers of PN junctions, wherein at least one of said layers is reversed relative to the other said layers.

2. A vertical multi-junction photovoltaic cell as set forth in claim 1, wherein said plurality of layers comprises a single stack of all of said layers integrally bonded together, and at least two electrical connections fixed to said single stack.

3. A vertical multi-junction photovoltaic cell as set forth in claim 2, wherein said at least one layer is located at one end of said single stack.

4. A vertical multi-junction photovoltaic cell as set forth in claim 2, wherein said at least one layer is located in said single stack at a location other than an end of said single stack.

5. A vertical multi-junction photovoltaic cell as set forth in claim 1, wherein said at least one layer is substantially the same as other ones of said plurality of layers, except for its reversed orientation.

6. A vertical multi-junction photovoltaic cell as set forth in claim 1, wherein said at least one layer, in addition to being reversed, is also different than the other layers of said plurality of layers in at least one of doping architecture, material, or thickness.

7. A vertical multi-junction photovoltaic cell as set forth in claim 1, wherein said at least one layer is structured to optimize its ability to limit reverse current through said multi-junction photovoltaic cell.

8. A vertical multi-junction photovoltaic cell as set forth in claim 1, further comprising an opaque covering for blocking light from impinging on said at least one reversed layer.

9. An array of vertical multi-junction photovoltaic cells comprising a plurality of vertical multi-junction photovoltaic cells, each cell having a plurality of layers of PN junctions, all of said layers aligned so that said PN junctions are in electrical series with one another, and at least one other layer of PN junction aligned so that said other layer is in electrical anti-series with said plurality of layers of PN junctions, wherein at least two of said plurality of vertical multi-junction photovoltaic cells are interconnected in parallel with one another directly, without any intervening reverse-current limiting elements.

10. An array of vertical multi-junction photovoltaic cells as set forth in claim 9, wherein said at least two of said plurality of vertical multi-junction photovoltaic cells are disposed closely together in a dense array adapted for installation at the focus of an optical concentrator.

11. An array of vertical multi-junction photovoltaic cells as set forth in claim 9, wherein said plurality of layers of PN junctions of each said cell comprises a single stack of all of said layers integrally bonded together, and further wherein said at least one other layer is located at one end of said single stack.

12. An array of vertical multi-junction photovoltaic cells as set forth in claim 9, wherein said plurality of layers of PN junctions of each said cell comprises a single stack of all of said layers integrally bonded together, and further wherein said at least one other layer is located within said single stack and not at one end thereof.

13. An array of vertical multi-junction photovoltaic cells as set forth in claim 9 wherein said at least one other layer is substantially the same as individual ones of said plurality of layers of PN junctions, except for its reversed orientation.

14. An array of vertical multi-junction photovoltaic cells as set forth in claim 9 wherein said at least one other layer, in addition to being reversed, is also different than individual ones of said plurality of layers of PN junctions in at least one of doping architecture, material, or thickness.

15. A method of making a vertical multi-junction photovoltaic cell comprising the steps of stacking a plurality of wafer elements one on top of the other in a common orientation, adding to said stack at least one additional wafer element in a reversed orientation relative to the other wafer elements of said stack to thereby form a combined stack including a reversed wafer element, dividing said combined stack into individual die, and further processing said individual die to form said vertical multi-junction photovoltaic cells.

16. A method as set forth in claim 15, wherein said step of stacking a plurality of wafer elements comprises the step of stacking a plurality of wafer elements where each said wafer element is a portion of a wafer.

17. A method as set forth in claim 15, wherein said step of stacking a plurality of wafer elements comprises the step of stacking a plurality of wafers.

18. A method as set forth in claim 15, wherein said step of adding to said stack comprises the step of adding said at least one additional wafer element in reversed orientation at one end of said stack.

19. A method as set forth in claim 15, wherein said step of adding to said stack comprises the step of adding said at least one additional wafer element in reversed orientation at a location within said stack other than one end thereof.
